(19) United States
(12) Patent Application Publication
(10) Pub. No.: US 2018/0072078 A1
(43) Pub. Date: Mar. 15, 2018

(54) STAMPS AND OVERLAYS FOR PRODUCING ANIMATED IMAGES AND MOTION EFFECTS

(71) Applicant: Luciana Caballero, Boynton Beach, FL (US)

(72) Inventor: Luciana Caballero, Boynton Beach, FL (US)

(21) Appl. No.: 15/674,906

(22) Filed: Aug. 11, 2017

Related U.S. Application Data
(60) Provisional application No. 62/394,376, filed on Sep. 14, 2016.

(51) Int. Cl. B41J 27/04; B44C 1/24; G06T 13/80; G03F 7/00; G03F 7/105; B41M 7/00; B42D 25/00

(52) U.S. Cl. CPC B41J 27/04; B44C 1/24; G06T 13/80; B42D 25/00; G03F 7/105; B41M 7/0027; G03F 7/0015

(57) ABSTRACT

A versatile system, kit and method for a printing kinegram imagery with inked stamps enables users to place such imagery at desired, arbitrary locations on paper or other substrates, particularly useful in arts and crafts projects such as scrapbooking, and the like. A stamp has a surface having a plurality of raised and non-raised regions to produce a coded, printed kinegram image on a sheet of paper or other substrate. An overlay sheet with transparent and non-transparent areas corresponding to the raised and non-raised regions of the stamp, such that when the overlay is placed over the coded printed kinegram image, and one or both of the coded printed kinegram image and overlay are moved relative to one another, an illusion of movement or animation is imparted to a viewer. At least a portion of the stamp is transparent to facilitate precise placement of the coded printed kinegram image.

### REFERENCE TO RELATED APPLICATIONS

This application claims priority to U.S. Provisional Patent Application Ser. No. 62/394,376, filed Sep. 14, 2016, the entire content of which is incorporated herein by reference.

### FIELD OF THE INVENTION

This invention relates generally to stamps and, in particular, to stamps capable of transferring and producing images that will animate and have motion effects.

### BACKGROUND OF THE INVENTION

Inked stamps have been used on documents for centuries. The use of rubber stamps for hobbyist and craft projects, including “scrapbooking” and the like, are also well known.

A problem with traditional stamps is that the wooden block to which the stamp is mounted obstructs the view of the person making the stamp, causing the stamped image to be poorly located. To improve stamp positioning, new types of stamps have been created, including “cling” stamps and “clear” stamps. Clear stamps are made from a transparent plastic material such as a photopolymer, whereas cling stamps are rubber-like with a foam backing. Both clear and cling stamps are mounted to clear acrylic or plastic blocks instead of wooden blocks, enabling the individual placing this stamp to see through the block and control exactly where the image will be placed. The stamps can also be mounted on a craftwork accessory such as a stamp platform for precision stamping, this platform allows the user to stamp accurately and repeatedly with a clean and precise impression.

Traditionally, stamping has been used to place stationary images on paper. The images can be enhanced with coloring, or by using a “die cut” to cut it from the paper. Embossing may be used to add dimensionality to a stamped image.

A kinegram is multi-part image that imparts movement or animation. A traditional kinegram has two components: (1) an underlying picture with a complex striped pattern (a “coded” image); and (2) an overlay of alternating clear and solid stripes placed over the coded image. When the overlay is moved across the coded image, an illusion of movement is created. The overlay is typically made and printed on a sheet of clear plastic, though a “lenticular” sheet, screen, stencil, die cut, paper punch tool or laser cut paper and other materials such as plastic, acetate, etc.; may alternatively be used to produce the desired motion effect.

While kinegrams have been used in greeting cards and children's books, the codes images are pre-printed, and the device for producing the animated effect is stationary. A user cannot manipulate the coded image, or its placement, and the kinegram can only be viewed. While the prior art has provided a variety of stamping technologies, it has failed to provide a method to transfer and apply the unique coded images and visual qualities of kinegram technology on the scale required for use in stamping, card making, scrapbooking, papercrafting, mixed media, etc.

It would therefore be desirable to provide a method for transferring kinegram images to any arbitrary location desired by a user. It would be further advantageous to allow a user to apply multiple kinegram images of their choosing on any part of a project to achieve an animated or motion effect. This would provide a user with the freedom to combine kinegram images so as to create an animated scene.

### SUMMARY OF THE INVENTION

This invention resides in a versatile system and method for a creating kinegram imagery with inked stamps, thereby enabling users to place such imagery at desired, arbitrary locations on paper or other substrates. While the invention finds utility in other areas, it is particularly useful in arts and crafts projects such as cardmaking, scrapbooking, and the like.

A stamp and corresponding overlay for producing a kinegram image according to the invention at least comprises a stamp and an overlay. The stamp has a surface having a plurality of raised regions separated by non-raised regions, whereby when the raised regions are inked and stamped onto a substrate, a coded printed kinegram image is produced. The overlay sheet with transparent and non-transparent areas corresponding to the raised and non-raised regions of the stamp, such that when the overlay is placed over the coded printed kinegram image, and one or both of the coded printed kinegram image and overlay are moved relative to one another, an illusion of movement or animation is imparted to a viewer. While the “non-transparent” as used herein preferably means “opaque,” “non-transparent should be taken to include areas that are less transparent than the transparent areas, including semi-transparent.

The raised regions of the stamp and the transparent areas of the overlay sheet may be elongated, parallel, and proportional to one another, or the regions and areas may be configured about a center point to produced ‘spoked wheel’ type kinegrams. Indeed, the invention is not limited in terms of the type/style of kinegrams produced, such that the size and proportionality of the stamp regions and overlay may be adjusted to achieve a desired degree of animation or movement. Also, the current invention includes a stamp that will transfer the underlying coded image with only one stamping motion onto the surface. The image can also be separated into 2, 3 or more individual stamps, so that in order to produce the coded kinegram image, the user will stamp each individual image on top of the other so that the final kinegram image is achieved.

In the preferred embodiments, at least a portion of the stamp is transparent to facilitate precise placement of the coded printed kinegram image onto the substrate. If a mounting block is used, at least a portion of the mounting block is transparent to facilitate the precise placement. The mounting block does not need to be transparent and many different materials and object can be used for mounting the stamp such as foam and a stamp positioner device. The stamp can also be self-inking.

The stamp may be composed from any appropriate materials, including but not limited to natural rubbers; synthetic rubbers including thermoplastic plasticized rubbers (TPRs); silicones; and photopolymers. Likewise, the overlay may be made from any appropriate materials, including but not limited to acetates; plastic films; die-cut paper, laser cut cardstock or other materials; and lenticular sheets.

### BRIEF DESCRIPTION OF THE DRAWINGS

FIG. 1A shows is a group of transparent stamps used by a user to create an underlying image in accordance with this invention;

FIG. 1B shows how a collection of stamps can be stored between two transparent plastic sheets;

FIG. 1C illustrates the process by which, when a user decides to place a kinegram image on a page, they lift the top plastic sheet and mount a stamp on an acrylic block;

FIG. 2 is a close-up view of a stamp and an acrylic mounting block according to the invention that is used to hold the stamp and to apply the transfer material (ink, paint, etc.,) for the underlying image to be transferred on the receiving surface;

FIG. 3 is a stamp mounted on the clear block according to the invention;

FIG. 4 is a mounted stamp pressed onto an inkpad that is used to transfer the coded image onto a surface according to the invention;

FIG. 5 depicts a user pressing the inked stamp onto a surface;

FIG. 6 shows a resulting, coded image on the surface according to the invention;

FIG. 7 is a close-up view of the resulting coded image according to the invention;

FIG. 8 is a cross-section of a stamp that has a base portion and has a surface comprising of a plurality of raised regions separated by non-raised regions according the invention;

FIG. 9 illustrates various overlays that can be used to produce the animation/motion effect of the underlying coded images according to the invention;

FIG. 10 is a metal die cut that is used to cut out lines in a material so that the user can create an overlay for use with the underlying coded image in FIG. 2;

FIG. 11 is an alternative metal die cut that is used to cut out lines in a material so that the user can create an overlay for use with the underlying coded image in FIG. 2;

FIG. 12 is a stamp that is separated into three different parts in order to produce a coded image as in FIG. 6;

FIG. 13A is a stamp mounted on a foam block;

FIG. 13B shows an image produced with the stamp of FIG. 13A;

FIG. 14 is an overlay that is used to create the motion effect with the underlying image. The overlay is created by pre-cutting the lines into a material. This overlay can be cut with a laser or any device to produce the desired result;

FIG. 15 is a lenticular stamp and mounting block according to this invention;

FIG. 16 is an inkpad for use with stamps;

FIG. 17 is a lenticular coded image produced by a stamp, and a lenticular lens overlay according to the invention;

FIG. 18 is the resulting image created from combining the stamped lenticular image and lenticular lens to create animation and motion effects when moved by the user; and

FIG. 19 is a close-up diagram of the lenticular lens and how it allows for the illusion of animation and motion effects when it is moved with the underlying image.

### DETAILED DESCRIPTION OF THE PREFERRED EMBODIMENTS

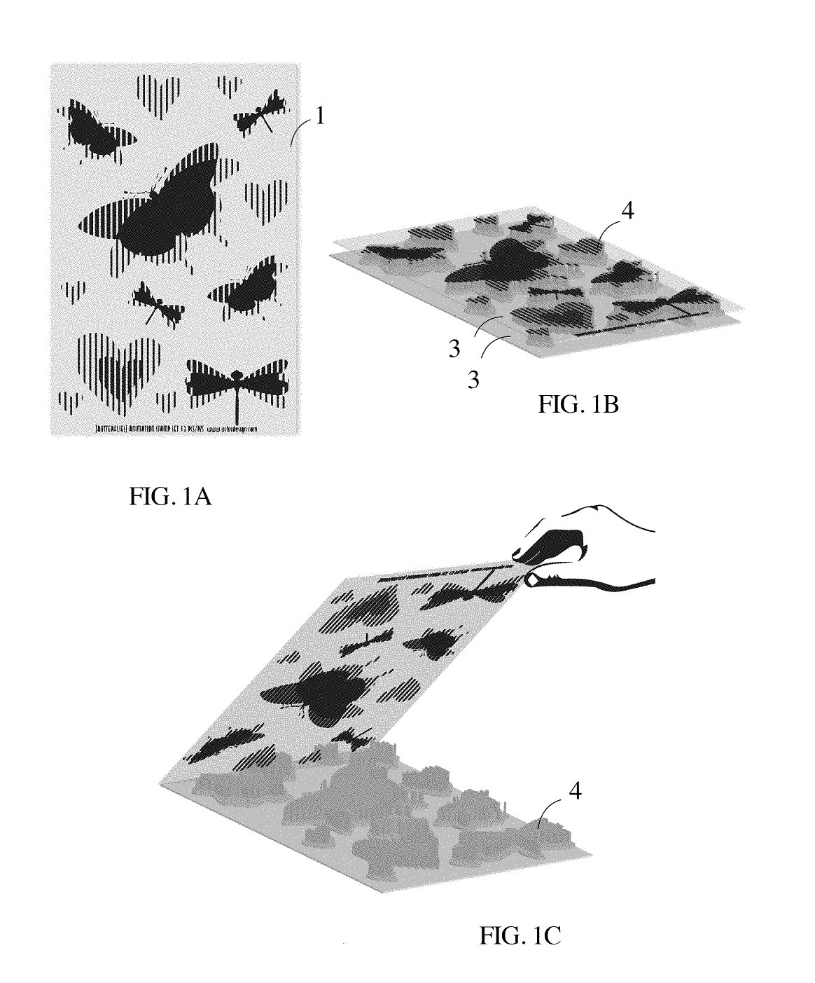

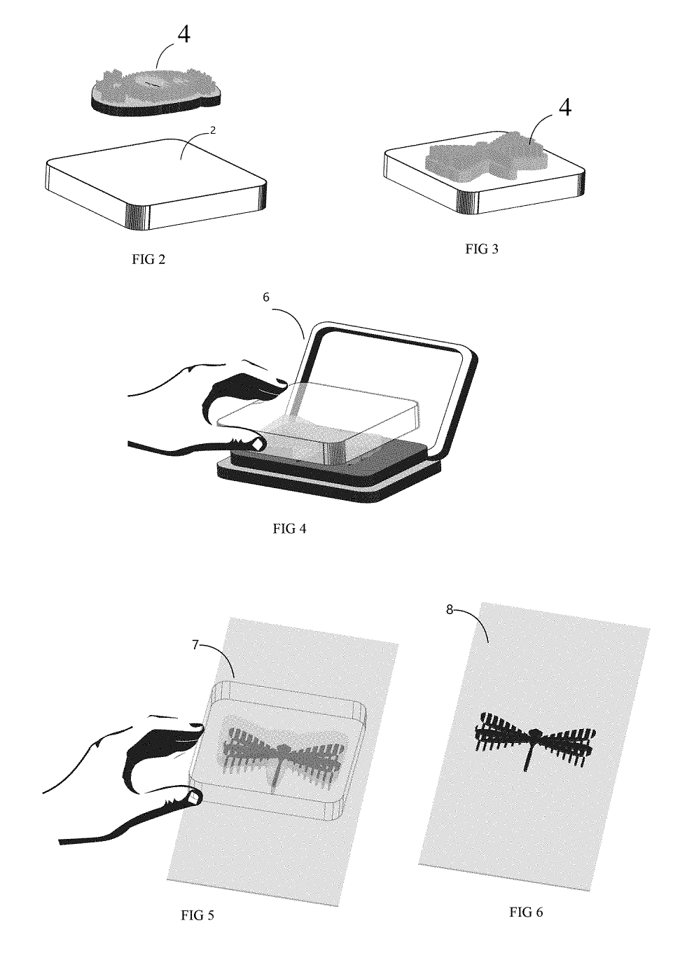

In broad and general terms, this invention enables users to produce kinegram images with rubber stamp technology, thereby allowing such images to be placed at will into arts and crafts projects including, but not limited to stamping, scrapbooking, cardmaking, papercrafting, mixed media, and other applications. The invention provides application and positioning devices (FIGS. 1, 2, 3) and methodologies for the placement and transfer of unique coded images onto surfaces, such that users are able to create the illusion of animated images in their craft projects.

In accordance with the invention, a conventional two-dimensional image is converted into a coded image. The coded image is then transferred to a stamp, whereby a user can then apply a transfer material such as ink or paint and place the coded image at one or more desired locations. In preferred embodiments, a clear or cling stamp is used with a clear block in order to facilitate precise positioning.

The stamp is specially designed and manufactured with a plurality of raised print surfaces separated by depressed non-print surfaces such that the plurality of raised print surfaces are proportionally spaced to produce a desired animated effect (FIG. 8). The plurality of raised print surfaces creates an ink transfer surface for applying the image onto the surface.

FIG. 1A shows a group of transparent stamps 4 that are used to create the underlying image in FIG. 6. The collection of stamps 4 are stored between two transparent plastic sheets 3 (FIG. 1B). When a user decides to place a kinegram image on a page, they lift the top plastic sheet 3 (FIG. 1C), mount the stamp 4 on an acrylic block 2 (FIG. 2), press the desired stamp 4 onto an inkpad 6 (FIG. 4), and then press the stamp 4 onto the paper 8 (FIG. 5), to create the underlying image FIG. 6. The transparent structure of the stamp 4 allows the user to precisely position the stamp 4 at the correct location on the project.

The transparent (i.e., photopolymer) animated stamp allows the user to see exactly where the image will be placed on a page 7 (FIG. 5). As a result, even a novice crafter can produce polished and professional looking craft projects with kinegram images. Those skilled in the art will recognize that, in addition to photopolymer, other materials can be used to stamp the underlying image used by kinegram technology. For example, silicone and TPR are two materials that can be used to create stamps. However, photopolymer has been found to provide superior results when transferring ink from the stamp to the page hosting the underlying image.

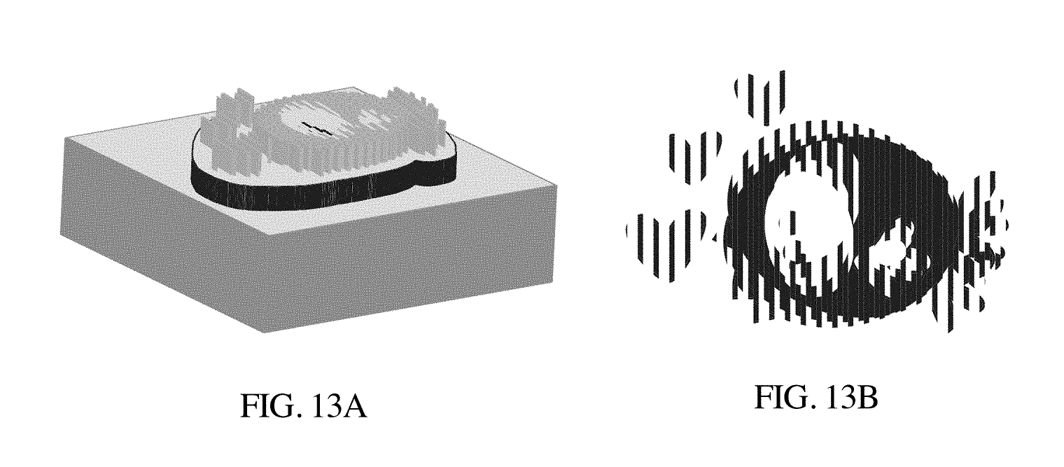

FIG. 8 is a cross-section of a stamp that has a base portion 17 and a surface 16 comprising of a plurality of raised regions 15 separated by non-raised regions according the invention. FIG. 13 is an example of the stamp mounted on a foam block. Those skilled in the art will recognize that the stamp can be mounted on a multitude of material in order to produce the same result. While the use of an acrylic block is advantageous, it is not the only method of inking and using the stamps described in this invention.

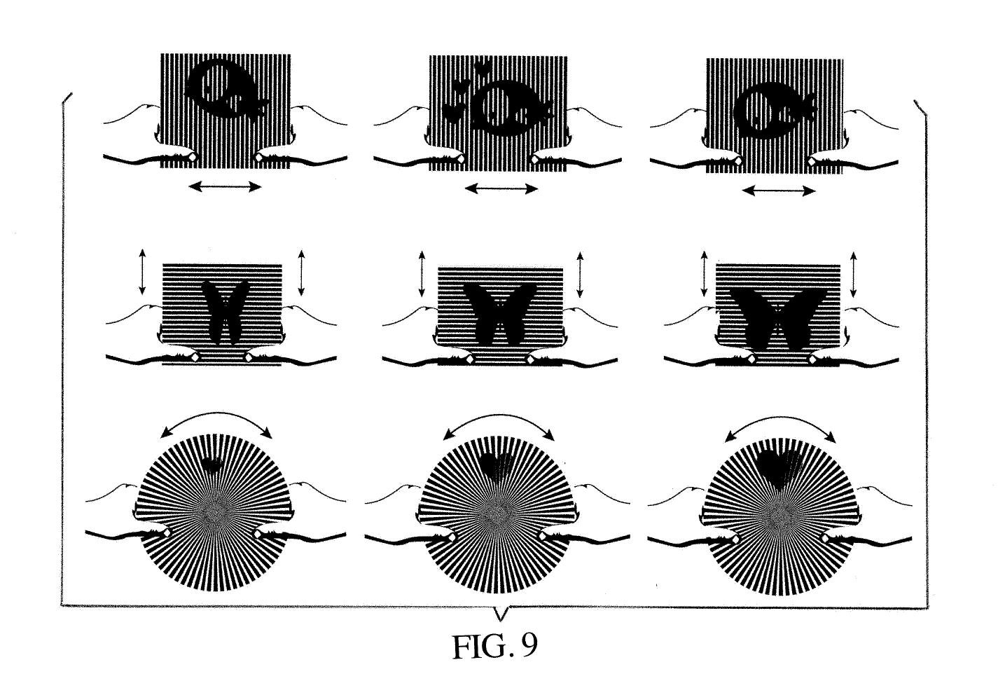

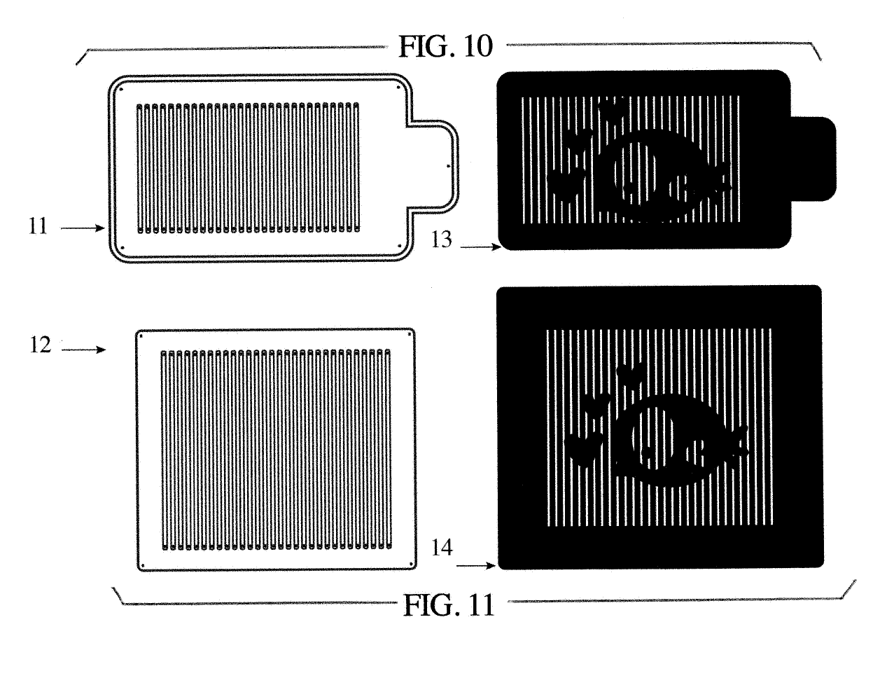

Once the coded image is combined with an overlay of matching proportional lines and spaces, a particular visual effect is achieved. More particularly, by placing the overlay containing proportional lines over the unique coded image and slowly moving it or moving the image, this creates an exciting new and unique visual feature that has not previously been possible with inked stamp technology (FIG. 9).

A number of different embodiments of an overlay containing proportional clear or see-through spaces and solid sections can be placed over the unique coded images and slowly moved to create the illusion of motion. Alternatively, the image itself can be moved while the overlay is stationary to produce the same effect.

The overlay can be made using an acetate sheet with the proportional lines printed, or a die cut can be used to “cut out” the proportional lines from any paper or material to product the same result. FIG. 10 is an example of the die cut tool 11 that can be used to produce an overlay 13 with proportional lines. FIG. 11 is an alternative metal die cut 12 that is used to cut out lines in a material so that the user can create an overlay 14 for use with the underlying coded image in FIG. 2.

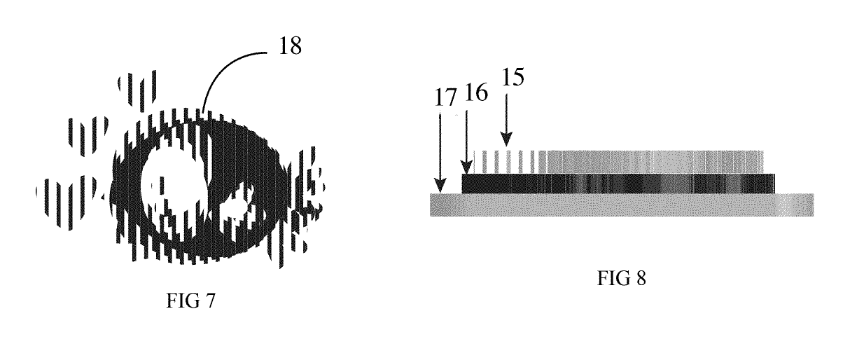

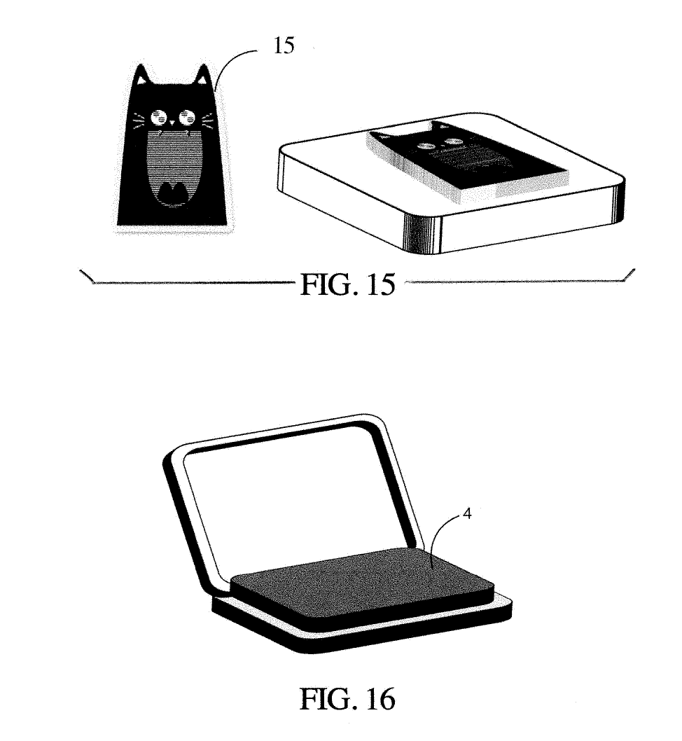

FIG. 7 is the acetate overlay 18 that can moved over the underlying image (FIG. 6) to create the illusion of motion. As a further alternative, a lenticular sheet 15 can be used as the overlay to produce the desired animated and motion effect (FIG. 15). The prepared coded images and overlay use precise measurements in relation to one another in order to produce an animated effect when the image or overlay is moved (FIGS. 6, 8).

Thus, through the use of a precise measurement of multiple image placements and a proportional overlay of clear and solid sections, an animated effect is created for the image. Those skilled in the art will recognize that any other material can be used as a substitute for the acetate overlay providing that it is suitable for its purposes.

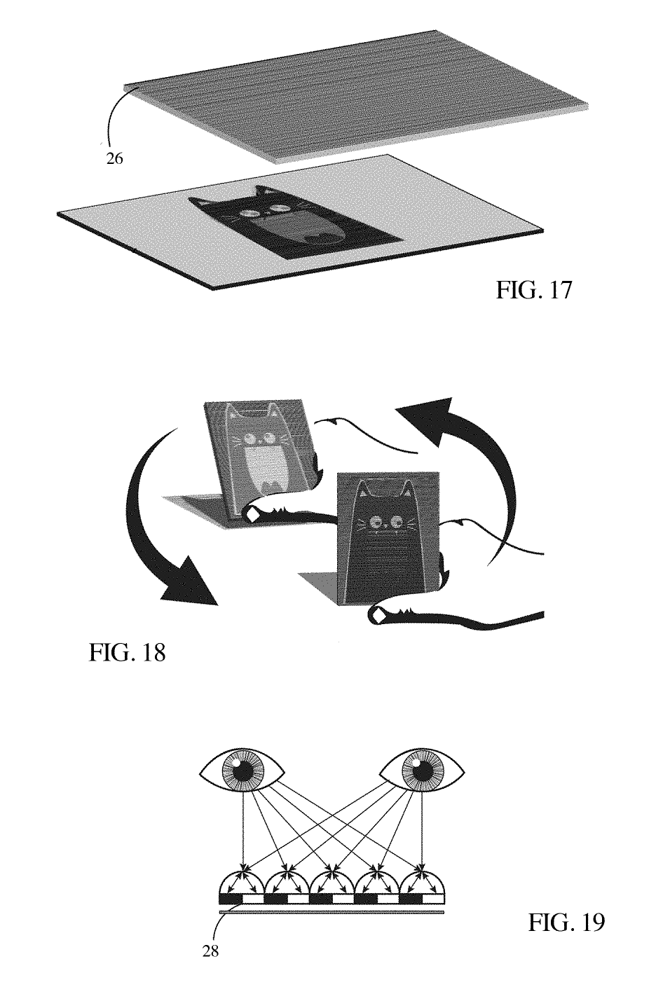

An alternative preferred embodiment replaces the overlay, discussed above, with a “lenticular” sheet 15 (FIG. 15). Lenticular sheets can be used to produce the same effect as the aforementioned overlay. Lenticular sheets can also be used with another type coded image that is turned into a stamp (FIG. 13A) to produce the image shown in FIG. 13B. This stamp is used to produce a slightly different motion effect, the motion effect is displayed in FIG. 18. The image can also be glued to the lenticular sheet to create a 3D image or an image that has a animation effect when it is moved (FIG. 17). FIG. 19 is a close-up diagram of the lenticular lens 28 and how it allows for the illusion of animation and motion effects when it is moved with the underlying image.

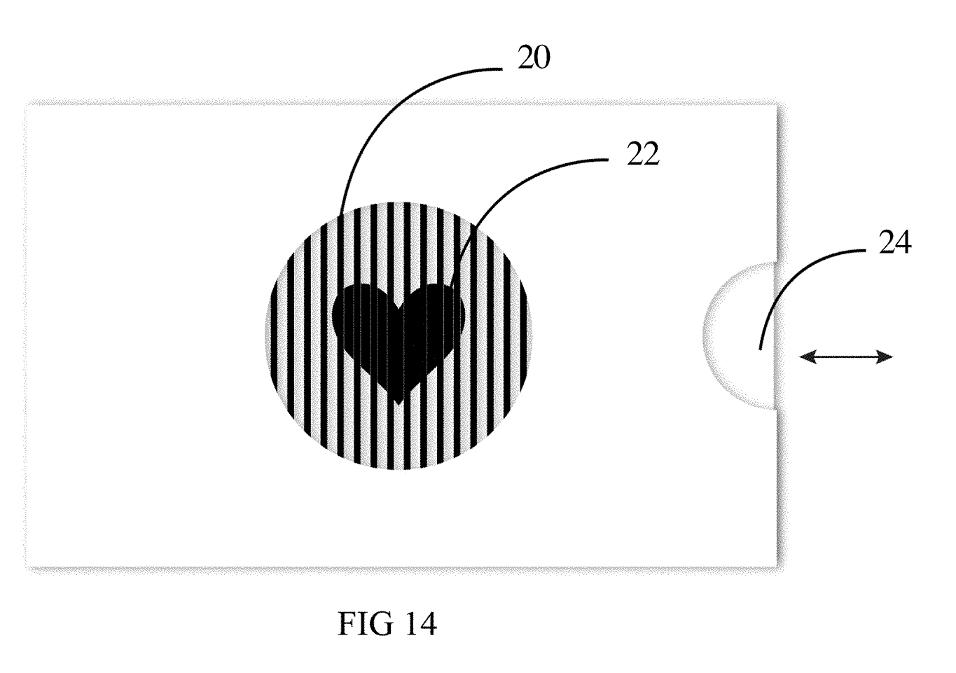

FIG. 14 is an overlay 20 that is used to create the motion effect with the underlying image 22. The overlay is created by pre-cutting the lines into a material. This overlay can be cut with a laser or any device to produce the desired result.

Another alternative preferred embodiment replaces the acetate overlay, or lenticular sheet, with an overlay created with paper (FIG. 10). By cutting proportional lined spaces out of the paper, it will replicate the lines of the acetate overlay. A colored piece of paper can be used if the lines cut are proportional in relation to the coded images. These lines can be cut using a die cut, paper punch tool, or it can be laser cut out of the paper. FIG. 17 is an example of the overlay 26 created but cutting the lines out of paper using a laser-cutting process.

In accordance with the invention, a user can place coded images wherever they would like, and use the overlay in whatever way they choose. A significant advantage is that the user is not limited to producing only one image. They can stamp the same image multiple times, or stamp multiple different images at locations in the craft project of their choosing. Likewise, they can have many animated images on the same page. As a result, the invention provides the user with enormous freedom.

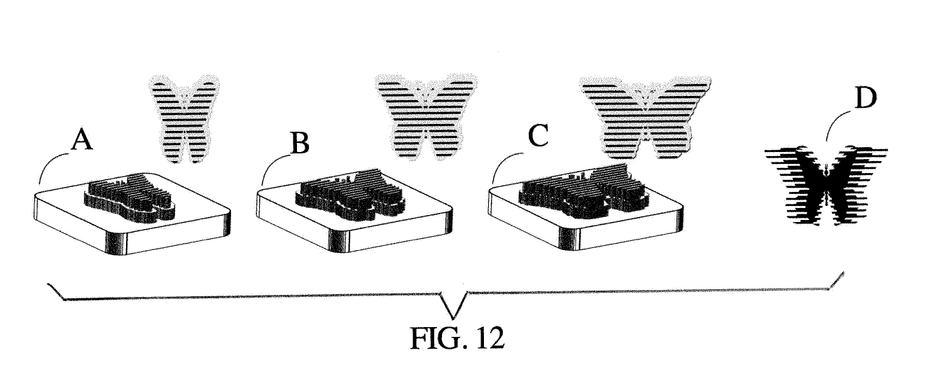

In another embodiment, the coded image is separated into three separate images and manufactured into three separate stamps A, B, C (FIG. 12). In this embodiment, the user will stamp three images on top of each other to produce the functional coded image D. There are tools in the market that the users can use to make this process easier. The stamps can be mounted on a craftwork accessory such as a stamp platform for precision stamping, that allows the user to stamp accurately and repeatedly with a clean and precise impression.

While the invention has been described with respect to a preferred embodiment thereof, it will be understood by those skilled in the art that various changes in detail may be made therein without departing from the spirit, scope, and teaching of the invention. For example, the number and types of stamps can vary, the size of the stamps can vary, the materials used to fabricate the stamps can vary, and/or using another method of transferring the image onto the surface, etc. Accordingly, the invention herein disclosed is to be limited only as specified in the following claims.

1. A stamp kit for a producing a kinegram animated image, comprising:
a stamp with a surface having a plurality of raised regions separated by non-raised regions, whereby when the raised regions are inked and stamped onto a substrate, a coded printed kinegram image is produced; and
an overlay with transparent and non-transparent areas corresponding to the raised and non-raised regions of the stamp, such that when the overlay is placed over the coded printed kinegram image, and one or both of the coded printed kinegram image and overlay are moved relative to one another, an illusion of movement or animation is imparted to a viewer.

2. The stamp kit of claim 1, wherein the raised regions of the stamp and the transparent areas of the overlay sheet are elongated, parallel, and proportional to one another.

3. The stamp kit of claim 1, wherein the raised regions of the stamp and the transparent areas of the overlay sheet form elongated, parallel, proportional, vertical lines.

4. The stamp kit of claim 1, wherein the transparent areas of the overlay sheet form spokes that radiate outwardly from a center point.

5. The stamp kit of claim 1, wherein at least a portion of the stamp is transparent to facilitate precise placement of the coded printed kinegram image onto the substrate.

6. The stamp kit of claim 1, including a mounting block that is at least partially transparent to facilitate precise placement of the coded printed kinegram image onto the substrate.

7. The stamp kit of claim 1, wherein the stamp is made from one of the following materials:
natural rubber;
synthetic rubber;
tpr;
silicone; and
photopolymer.

8. The stamp kit of claim 1, wherein the overlay is made from one of the following materials:
acetate;
plastic film;
die-cut paper;
a stencil; and
a lenticular sheet.

9. The stamp kit of claim 1, wherein the overlay is made by using a die-cut tool to cut proportional lines out of one of the following material:
paper;
cardstock;
plastic;
metal;
cardboard; and
wood.

10. The stamp kit of claim 1, wherein the overlay is made with a laser-cutting machine, and the transparent areas are pre-cut for use with coordinated animation stamps.

11. The stamp kit of claim 1, wherein the stamp is self-inking.

12. A stamp for a producing a kinegram animated image adapted for use with an overlay having transparent and non-transparent areas such that when the overlay is placed over the coded printed kinegram image, and one or both of the coded printed kinegram image and overlay are moved relative to one another, an illusion of movement or animation is imparted to a viewer, the stamp comprising:
a layer of material with a surface having a plurality of raised regions separated by non-raised regions, whereby when the raised regions are inked and stamped onto a substrate, a coded printed kinegram image is produced.

13. The stamp of claim 12, wherein the raised regions of the stamp are elongated, parallel, and proportional to one another.

14. The stamp of claim 12, wherein the raised regions of the stamp are elongated, parallel, proportional, vertical lines.

15. The stamp of claim 12, wherein the coded printed kinegram image forms spokes that radiate outwardly from a center point.

16. The stamp of claim 12, wherein at least a portion of the stamp is transparent to facilitate precise placement of the coded printed kinegram image onto the substrate.

17. The stamp of claim 12, including a mounting block that is at least partially transparent to facilitate precise placement of the coded printed kinegram image onto the substrate.

18. The stamp of claim 12, wherein the stamp is made from one of the following materials:
natural rubber;
synthetic rubber;
tpr;
silicone; and
photopolymer.

19. The stamp of claim 12, wherein the stamp is self-inking.
